(19) United States
(12) Patent Application Publication
(10) Pub. No.: US 2017/0345698 A1
(43) Pub. Date: Nov. 30, 2017

(54) ELECTROSTATIC CHUCK IMPEDANCE EVALUATION

(71) Applicant: Applied Materials, Inc., Santa Clara, CA (US)

(72) Inventors: Edward P. HAMMOND, IV, Hillsborough, CA (US); Zheng John YE, Santa Clara, CA (US); Abdul Aziz KHAJA, San Jose, CA (US)

(21) Appl. No.: 15/606,249

(22) Filed: May 26, 2017

Related U.S. Application Data
(60) Provisional application No. 62/342,563, filed on May 27, 2016.

(51) Int. Cl. H01L 21/683; H01L 21/48; G01R 31/28; H01L 21/687; H01L 21/67

(52) U.S. Cl. CPC H01L 21/6833; H01L 21/687; H01L 21/67276; G01R 31/2886; H01L 21/67248; H01L 21/4871; H01L 21/67253

(57) ABSTRACT

A support assembly for a semiconductor processing chamber is provided and includes a body comprising a heater, and a puck coupled to the body, the puck comprising a chucking electrode embedded in a dielectric material, wherein, when a radio frequency power of about 13.56 megahertz is applied to a substrate receiving surface of the body, an electrical resistance (R) of the body is about 0.460 Ohms, or less, and an electrical reactance (X) of the body is about 10.9 Ohms, or greater.

### CROSS-REFERENCE TO RELATED APPLICATION

This application claims benefit of U.S. Provisional Patent Application Ser. No. 62/342,563, filed May 27, 2016, which is hereby incorporated by reference herein.

### BACKGROUND

### Field

Embodiments of the disclosure generally relate to an electrostatic chuck having a radio-frequency impedance, and methods and apparatus for determining radio-frequency impedance in an electrostatic chuck, as well as methods for testing and manufacture thereof.

### Description of the Related Art

In the manufacture of electronic devices on substrates, such as semiconductor wafers and displays, many vacuum processes are utilized, such as chemical vapor deposition (CVD), physical vapor deposition (PVD), etch, implant, oxidation, nitridation, or other processes, to form the electronic devices. The substrates are typically processed one by one on an electrostatic chuck in a substrate processing chamber. To increase throughput, modern manufacturers often utilize a plurality of these substrate processing chambers operating in parallel (i.e., running a common process recipe). Each of the processing chambers may be the same make and model and are typically configured to process a substrate according to the common recipe. Thus, a plurality of substrates may be processed within the same time period to produce identical products.

While the processing chambers may be seemingly identical, subtle variations may exist between the processing chambers. The variations may require adjustment of the process parameters on one or more of the processing chambers to obtain “chamber match” or “chamber matching.” One methodology to reduce chamber on-substrate results in processing chambers utilizing radio frequency (RF) induced plasma processes is to modify the RF power parameters of a particular processing chamber to compensate for a chamber-to-chamber variation in order to produce a product that is in tolerance with other products that are processed in other processing chambers according to the common recipe. However, to modify the RF power parameters to obtain chamber matching, additional hardware is typically required. The additional hardware is often costly and typically does not address the root cause of the chamber-to-chamber variation. In addition, the electrostatic chuck plays a role in the deposition of dielectric films in chambers. The chuck has multiple functions and one being providing a return path for the radio-frequency power applied to generate the plasma. Characterizing the RF impedance of the chuck is one way to ensure that the chuck has consistent process performance and to improve chamber matching.

Accordingly, it is desirable to reduce the chamber-to-chamber variations as well as on-substrate results.

### SUMMARY

In one embodiment, a support assembly for a semiconductor processing chamber is provided and includes a body comprising a heater, and a puck coupled to the body, the puck comprising a chucking electrode embedded in a dielectric material, wherein, when a radio frequency power of about 13.56 megahertz is applied to a substrate receiving surface of the body, an electrical resistance (R) of the body is about 0.460 Ohms, or less, and an electrical reactance (X) of the body is about 10.9 Ohms, or greater.

In another embodiment, a processing tool is provided that includes a plurality of processing chambers configured to run the same recipe on a respective substrate disposed on a support assembly within each of the processing chambers, wherein an impedance (Z) of each of the support assemblies is substantially the same.

In another embodiment, a testing fixture is provided that includes a ground plate, a conductive plate to electrically couple to a substrate receiving surface of a support assembly, a dielectric spacer sandwiched between the conductive plate and the ground plate, wherein the conductive plate has a center conductor disposed through the dielectric spacer and the ground plate, and an interface that couples with a network analyzer that provides radio frequency power to the conductive plate and the substrate receiving surface

### BRIEF DESCRIPTION OF THE DRAWINGS

So that the manner in which the above-recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 is a partial cross sectional view showing an illustrative processing chamber.

FIG. 2 is a schematic side view of one implementation of a test fixture disposed on a support assembly that may be used in the processing chamber of FIG. 1.

FIG. 3 shows one embodiment of an equivalent test circuit provided by the fixture shown in FIG. 2.

FIG. 4 is a schematic side view of one embodiment of a measurement jig for determining impedance of a support assembly.

FIG. 5 is a schematic view of one embodiment of a fixture calibration jig that may be used to test the test fixture of FIG. 2 or the measurement jig of FIG. 4.

FIG. 6 is a schematic top plan view of a processing tool having support assemblies as described herein.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments described herein generally relate to an electrostatic chuck for use in a vacuum processing chamber. The electrostatic chuck has as one role facilitating transmission of radio frequency (RF) power in the chamber as well as chucking a substrate thereon. This application discloses a fixture for testing the electrical characteristics of an electrostatic chuck as well as methods for manufacture thereof. The methods and apparatus as described herein reduce within substrate variations as well as chamber to chamber variations which enable chamber matching for operating plural processing chambers in parallel.

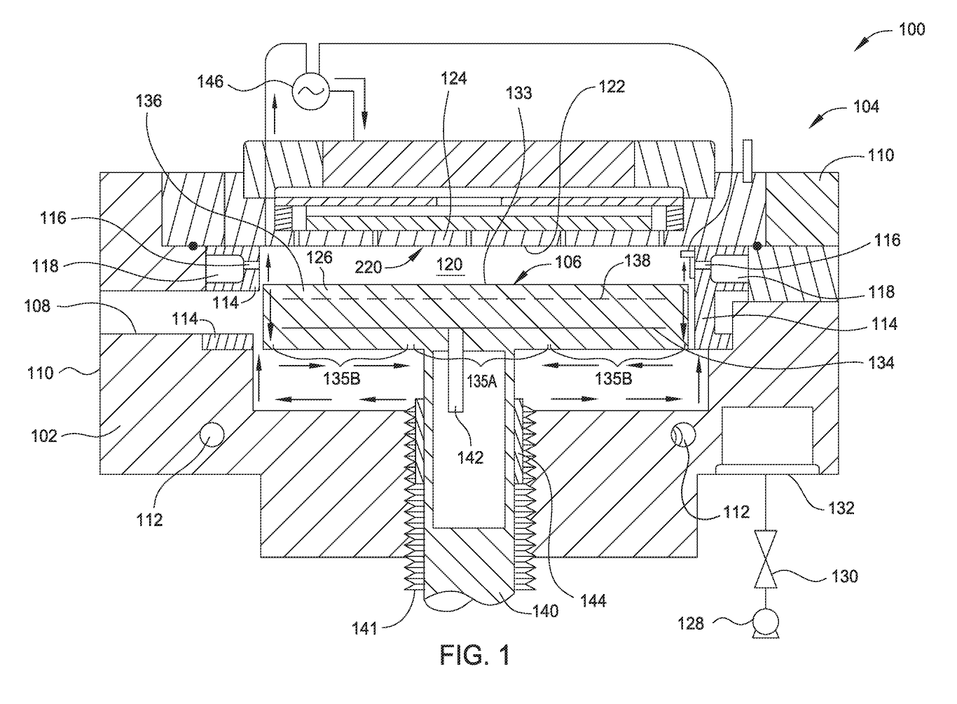

FIG. 1 is a partial cross sectional view showing an illustrative processing chamber 100. In one embodiment, the processing chamber 100 includes a chamber body 102, a lid assembly 104, and a support assembly 106. The lid assembly 104 is disposed at an upper end of the chamber body 102, and the support assembly 106 is at least partially disposed within the chamber body 102. The processing chamber 100 and the associated hardware are preferably formed from one or more process-compatible materials, such as aluminum, anodized aluminum, nickel plated aluminum, nickel plated aluminum 6061-T6, stainless steel, as well as combinations and alloys thereof, for example.

The chamber body 102 includes a slit valve opening 108 formed in a sidewall 110 thereof to provide access to the interior of the processing chamber 100. The slit valve opening 108 is selectively opened and closed to allow access to the interior of the chamber body 102 by a substrate handling robot (not shown). In one embodiment, a substrate can be transported in and out of the processing chamber 100 through the slit valve opening 108 to an adjacent transfer chamber and/or load-lock chamber, or another chamber within a cluster tool.

In one or more embodiments, the chamber body 102 includes a channel 112 formed therein for flowing a heat transfer fluid therethrough. The heat transfer fluid can be a heating fluid or a coolant and is used to control the temperature of the chamber body 102 during processing and substrate transfer. The temperature of the chamber body 102 is important to prevent unwanted condensation of the gas or byproducts on the chamber walls. Exemplary heat transfer fluids include water, ethylene glycol, or a mixture thereof. An exemplary heat transfer fluid may also include nitrogen gas.

The chamber body 102 can further include a liner 114 that surrounds the support assembly 106. The liner 114 is preferably removable for servicing and cleaning. The liner 114 can be made of a metal such as aluminum, or a ceramic material. However, the liner 114 can be any process compatible material. The liner 114 can be bead blasted to increase the adhesion of any material deposited thereon, thereby preventing flaking of material which results in contamination of the processing chamber 100.

In one or more embodiments, the liner 114 includes one or more apertures 116 and a pumping channel 118 formed therein that is in fluid communication with a vacuum system. The apertures 116 provide a flow path for gases into the pumping channel 118, which provides an egress for the gases within the processing chamber 100. The apertures 116 allow the pumping channel 118 to be in fluid communication with a processing region 120 within the chamber body 102. The processing region 120 may be defined by a lower surface 122 of the lid assembly 104 (e.g., a faceplate 124) and an upper surface 126 (e.g., a substrate receiving surface) of the support assembly 106. The processing region 120 may be surrounded by the liner 114. The apertures 116 may be uniformly sized and evenly spaced about the liner 114. However, any number, position, size or shape of apertures may be used, and each of those design parameters can vary depending on the desired flow pattern of gas across the substrate receiving surface.

The vacuum system can include a vacuum pump 128 and a throttle valve 130 to regulate flow of gases through the processing chamber 100. The vacuum pump 128 is coupled to a vacuum port 132 disposed on the chamber body 102 and therefore, in fluid communication with the pumping channel 118 formed within the liner 114.

The support assembly 106 comprises a body 133 that includes an electrostatic chuck with a heater 134 embedded therein. The body 133 may comprise an electrically conductive material such as aluminum or a dielectric material such as a ceramic material. The support assembly 106 includes a puck 136 disposed on the body 133 that may be formed of a dielectric material, such as a ceramic material. The puck 136 (e.g., an electrostatic chuck) comprises a chucking electrode 138 that may be an electrically conductive mesh material adapted to couple with RF power. The chucking electrode 138 may comprise a mesh of a metal or metal alloy that is embedded within the puck 136. The chucking electrode 138 may be configured as a mono-polar electrode or a bi-polar electrode. The heater 134 may include inner heating elements 135A and outer heating elements 135B. The heater 134 may comprise a resistive heating element comprising a metal or metal alloy that is embedded within the body 133 beneath the chucking electrode 138.

A shaft 140 of the support assembly 106 may be coupled to an actuator that may vary a distance between the faceplate 124 of the lid assembly 104 and the substrate receiving surface 126 of the support assembly 106. The shaft 140 may include a heater rod 142 that electrically couples to the heater 134. The shaft 140 may be at least partially surrounded by a cooling hub 144 that may cool the shaft 140 during operation. Bellows 141 are sometimes utilized to promote sealing of the processing region 120 between the shaft 140 and the chamber body 102.

In operation, a substrate (not shown) may be chucked to the substrate receiving surface 126 of the support assembly 106. RF power from a RF system 126 is applied to the lid assembly 104 which travels to the faceplate 124 of the lid assembly 104. The support assembly 106 may function as an electrode relative to the faceplate 124 of the lid assembly 104 and any gases between the faceplate 124 and the substrate receiving surface 126 of the support assembly 106 may be excited into a plasma in order to etch the substrate and/or deposit materials thereon. As indicated schematically by arrows, returning RF power travels along one or more surfaces of the support assembly 106, portions of the chamber body 102, portions of the shaft 140, portions of surfaces of the bellows 141, surfaces of the liner 114, and surfaces of the cooling hub 144 in order to return to the RF system 146.

The support assembly 106 strongly impacts process results in the processing chamber 100. For example, the support assembly 106 maintains uniform temperature of a substrate thereon, provides RF ground for plasma formation, as well as electrostatically chucking the substrate. The support assembly 106 also provides repeatable, adjustable distances relative to the faceplate 124. However, one process parameter during RF application includes the impedance of the support assembly 106. Measuring the impedance of the support assembly 106 may determine operating parameters thereof. In one implementation, a testing apparatus and method is devised to determine impedance of the support assembly 106 and therefore provide a metric of whether the support assembly 106 is acceptable or not fit for service. In another implementation, a support assembly 106 is provided that has acceptable electrical characteristics according to methods described herein.

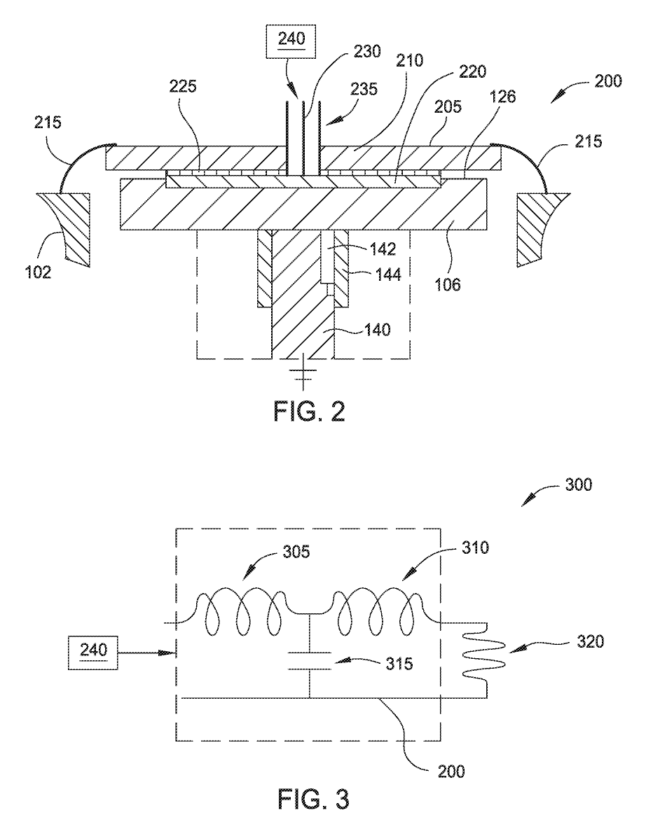

FIG. 2 is a schematic side view of one implementation of a test fixture 200 disposed on a support assembly 106 that may be used in the processing chamber 100 of FIG. 1. The fixture 200 includes a ground plane 205 that may comprise metallic plate 210. The metallic plate 210 may be aluminum. The ground plane 205 is couple to the chamber body 102 (sidewall 110) by one or more straps 215. A conductive plate 220 may be disposed on or adjacent to the substrate receiving surface 126 of the support assembly 106. The conductive plate 220 may be electrically insulated from the ground plane 205 by a dielectric spacer 225. The dielectric spacer 225 may be made of polymer material such as polytetrafluoroethylene (PTFE) or other suitable polymeric material. A conductor 230, such as a wire or cable, may be electrically coupled to the metallic plate 210. The conductor 230 may extend through an opening in the ground plane 205 and the dielectric spacer 225 to be exposed at an interface 235. A network analyzer 240 may be coupled to the conductor 230 of the fixture at the interface 235. A RF power is applied to the support assembly 106 by the network analyzer 240 via the conductor 230. The network analyzer 240 may provide a RF signal between about 10 kHz to about 104 MHz. The heater rod 142 may be shorted to the shaft 140 in order to test the support assembly 106.

FIG. 3 shows one embodiment of an equivalent test circuit 300 provided by the fixture 200 shown in FIG. 2. Values of inductance (plane (L) 305 and strap (L) 310) and capacitance (C) 315 may be determined in order to determine impedance (Z) 320 between the support assembly 106 and the chamber body 102. The effects of the fixture 200 should be accounted for and excluded to determine 320. For example, the values of inductance (305 and 310) and capacitance (315) may be calculated out of the circuit 300 to determine impedance 320. In one example, inductance of the plane (L) 305 may be about 5.31 nanohenrys (nH), inductance of the strap (L) may be about 7.86 nH, and capacitance of the dielectric spacer 225 (e.g., 315) may be about 368 picofarads (pF). These values may be excluded to determine impedance (320).

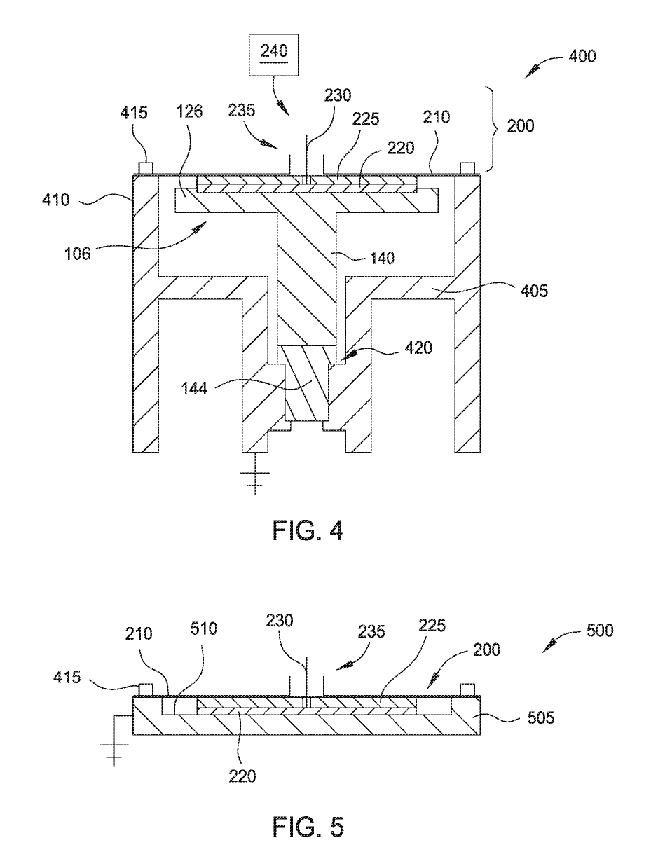

FIG. 4 is a schematic side view of one embodiment of a measurement jig 400 for determining impedance of a support assembly 106. The jig 400 may be used for mounting the support assembly 106 therein after removal from a chamber or before installation of the support assembly 106 into a chamber. The jig 400 includes a body 405 that resembles the chamber body 102 of the processing chamber 100 shown in FIG. 1. The body 405 may be made of aluminum or other conductive metal. The body 405 includes sidewalls 410 where the test fixture 200 shown in FIG. 2 may be fastened (using fasteners 415 such as bolts or screws). The body 405 also includes an opening 420 where the shaft 140 of the support assembly 106 may be inserted. The opening 420 may be sized to match dimensions of the cooling hub 144 similar to the mounting interface shown in FIG. 1.

The network analyzer 240 may be coupled to the conductor 230 of the fixture at the interface 235 and RF power may be applied to the support assembly 106 as described in FIG. 2. Impedance of the support assembly 106 may be determined as described above and the support assembly 106 may be approved for service or rated as non-usable within a particular system based on the determined impedance value. According to embodiments disclosed herein, impedance of the support assembly 106 may be determined such that multiple support assemblies having a substantially identical impedance may be provided, and the support assemblies having a substantially identical impedance may be utilized in a respective chamber in a tool. “Substantially identical” in this context is defined as an impedance of multiple support assemblies 106 that is within +/−3%. The substantially identical impedance of the multiple support assemblies may be used to provide chamber matching without the use of additional hardware.

FIG. 5 is a schematic view of one embodiment of a fixture calibration jig 500 that may be used to test the fixture of FIG. 2 or 4. The calibration jig 500 includes a body 505 that may be aluminum, or another conductive metal. An upper surface 510 of the body 505 may make electrical contact with the conductive plate 220 of the fixture 200 in order to test electrical characteristics of the test fixture 200. For example, the calibration jig 500 may measure short conditions and/or open conditions of the test fixture 200.

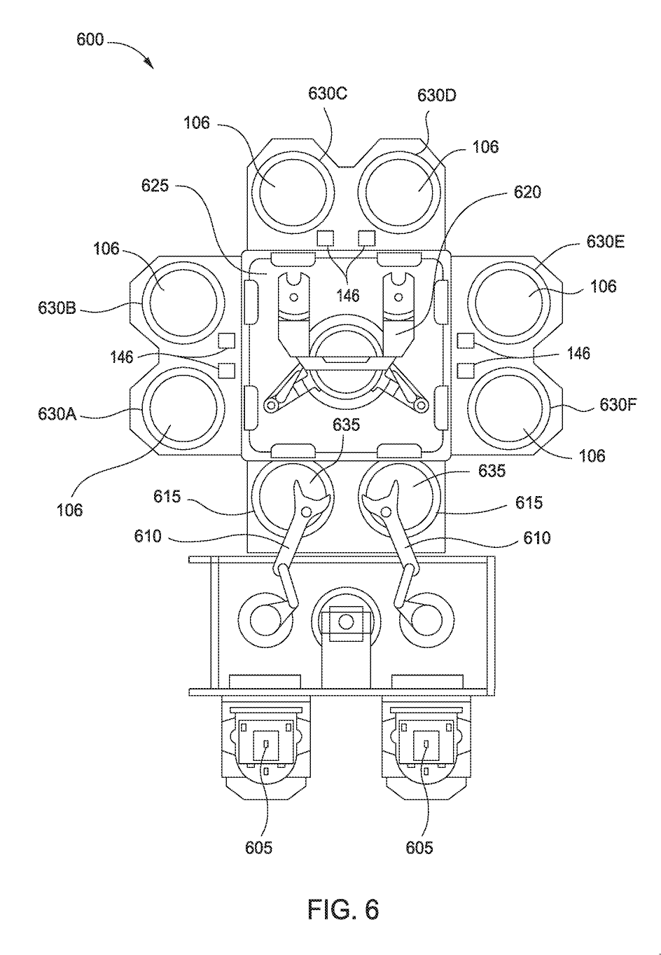

FIG. 6 is a schematic top plan view of a processing tool 600 according to one implementation. The processing tool 600, such as a cluster tool as shown in FIG. 6, includes a pair of front opening unified pods (FOUPs) 605 for supplying substrates, such as semiconductor wafers, that are received by robotic arms 610 and placed into load lock chambers 615. A transfer robot 620 is disposed in a transfer chamber 625 coupled to the load lock chambers 615. The transfer robot 620 is used to transport the substrates from the load lock chamber 615 one or more of a plurality of processing chambers 630A, 630B, 630C, 630D, 630E and 630F coupled to the transfer chamber 625.

The processing chambers 630A, 630B, 630C, 630D, 630E and 630F may include one or more system components for depositing, annealing, curing and/or etching a film on the substrate. Each of the processing chambers 630A, 630B, 630C, 630D, 630E and 630F include a support assembly 106 adapted to support a substrate 635 thereon. In one configuration, pairs of the processing chambers (e.g., 630A and 630B, 630C, 630D) may be used to deposit a film on a respective substrate utilizing the same recipe to produce an identical product. As such, process conditions should be substantially similar in each of the processing chambers 630A, 630B, 630C, 630D, 630E and 630F. “Substantially” in this context is defined as a match between chambers that is within +/−3%.

Each support assembly 106 of the processing tool 600 may have a similar impedance as confirmed using the embodiments as disclosed herein. As such, chamber matching is achieved in the processing tool 600 such that a substantially identical product may be provided on each substrate 635 in each of the processing chambers 630A, 630B, 630C, 630D, 630E and 630F. In particular, RF power to each of the processing chambers 630A, 630B, 630C, 630D, 630E and 630F may be substantially the same without the use of additional hardware. “Substantially” in this context is defined as providing RF power to each chamber that is within +/−3%.

The implementations above provide a manufacturing protocol and/or design parameters for an electrostatic chuck that may be utilized in different chambers running the same recipe with minimal to no variation in product and/or substrate-to-substrate results. Impedance of the support assembly 106 may be determined such that support assemblies may be assessed as “good” or “bad” based on a particular RF power applied thereto based on historical data of “good” support assemblies. For example, a “bad” support assembly may have an impedance that is higher by 4% to 8% at 350 kHz, or lower by 3% at 13.56 MHz. Other indicators of a “bad” support assembly may include a mesh capacitance of 4% to 7% less than “good” meshes. The fixture 200 as described herein may also be modified for other support assemblies having various patterns of RF mesh. For example, radial mesh patterns (zones), concentric mesh patterns (zones), azimuthal mesh patterns (zones) can be matched with similar shapes in the conductive plate (220 of FIG. 2) of the fixture 200. The fixture 200 can also be modified to test different portions of a single RF mesh. For example, the conductive plate 220 of the fixture 200 can be made as the quadrant of a circle and be used to evaluate different quadrants of a circular RF mesh.

While the foregoing is directed to implementations of the present disclosure, other and further implementations of the disclosure may be devised without departing from the basic scope thereof, and the scope thereof is determined by the claims that follow.

1. A support assembly for a semiconductor processing chamber, the support assembly comprising:
a body comprising a heater; and
a puck coupled to the body, the puck comprising a chucking electrode embedded in a dielectric material, wherein, when a radio frequency power of about 13.56 megahertz is applied to a substrate receiving surface of the body, an electrical resistance (R) of the body is about 0.460 Ohms, or less, and an electrical reactance (X) of the body is about 10.9 Ohms, or greater.

2. The support assembly of claim 1, wherein the heater comprises multiple zones.

3. The support assembly of claim 1, wherein the heater is disposed in the body at a depth greater than a depth of the chucking electrode as measured from the substrate receiving surface.

4. The support assembly of claim 1, further comprising:
a cooling hub coupled to a shaft.

5. The support assembly of claim 4, wherein a heater rod is positioned within the shaft.

6. The support assembly of claim 1, wherein the chucking electrode comprises a metal mesh.

7. A processing tool, comprising:
a plurality of processing chambers configured to run the same recipe on a respective substrate disposed on a support assembly within each of the processing chambers, wherein an impedance (Z) of each of the support assemblies is substantially the same.

8. The processing tool of claim 7, wherein each of the support assemblies comprise a body, and wherein, when a radio frequency power of about 13.56 megahertz is applied to a substrate receiving surface of the body, an electrical resistance (R) of the body is about 0.460 Ohms, or less, and an electrical reactance (X) of the body is about 10.9 Ohms, or greater.

9. The processing tool of claim 7, wherein each of the support assemblies comprise a body, and wherein, when a radio frequency power of about 350 kilohertz is applied to a substrate receiving surface of the body, an electrical reactance (X) of the body is about −161 Ohms, or greater.

10. The processing tool of claim 7, wherein each of the support assemblies comprise a body comprising a heater; and
a puck coupled to the body, the puck comprising a chucking electrode embedded in a dielectric material.

11. The processing tool of claim 10, wherein the heater comprises multiple zones.

12. The processing tool of claim 10, wherein the heater is disposed in the body at depth greater than a depth of the chucking electrode as measured from the substrate receiving surface.

13. The processing tool of claim 10, wherein each of the support assemblies further comprise:
a cooling hub coupled to a shaft.

14. The processing tool of claim 13, wherein a heater rod is positioned within the shaft.

15. The processing tool of claim 10, wherein the chucking electrode comprises a metal mesh.

16. A testing fixture, comprising:
a ground plate;
a conductive plate to electrically couple to a substrate receiving surface of a support assembly;
a dielectric spacer sandwiched between the conductive plate and the ground plate, wherein the conductive plate has a center conductor disposed through the dielectric spacer and the ground plate; and
an interface that couples with a network analyzer that provides radio frequency power to the conductive plate and the substrate receiving surface.

17. The fixture of claim 16, further comprising:
a measurement jig that supports the support assembly.

18. The fixture of claim 17, wherein the ground plate is coupled to a sidewall of the measurement jig.

19. The fixture of claim 18, wherein the ground plate is coupled to the sidewall of the measurement jig by a plurality of fasteners.

20. The fixture of claim 17, wherein the measurement jig comprises a body made of an electrically conductive material.
